(19) United States
(12) Patent Application Publication
(10) Pub. No.: US 2025/0159898 A1
(43) Pub. Date: May 15, 2025

(54) SEMICONDUCTOR MEMORY DEVICE

(71) Applicant: Samsung Electronics Co., Ltd., Suwon-si (KR)

(72) Inventors: Seung Jae BAIK, Suwon-si (KR); Tae Hun KIM, Suwon-si (KR); Jaeduk LEE, Suwon-si (KR); Jaehoon JANG, Suwon-si (KR); Jeehoon HAN, Suwon-si (KR)

(73) Assignee: Samsung Electronics Co., Ltd., Suwon-si (KR)

(21) Appl. No.: 18/804,202

(22) Filed: Aug. 14, 2024

(30) Foreign Application Priority Data
Nov. 10, 2023 (KR) 10-2023-0155440

(51) Int. Cl. H10B 53/20; H10B 43/10; H10B 43/27; H10B 43/35; H10B 51/10; H10B 51/20; H10B 53/10; H10B 63/00

(52) U.S. Cl. CPC H10B 53/20; H10B 43/10; H10B 43/27; H10B 43/35; H10B 51/10; H10B 51/20; H10B 53/10; H10B 63/30; H10B 63/84

(57) ABSTRACT

A semiconductor memory device may include a substrate, a stacked structure including semiconductor patterns stacked in a vertical direction with respect to an upper surface of the substrate, bit lines in contact with first sides of the semiconductor patterns and extending in a first direction parallel to the upper surface of the substrate, common source lines in contact with second sides of the semiconductor patterns and extending in the first direction, word lines penetrating the stacked structure and arranged two-dimensionally, and data storage patterns between the word lines and the stacked structure.

### CROSS-REFERENCE TO RELATED APPLICATIONS

This U.S. non-provisional patent application claims priority under 35 U.S.C. § 119 to Korean Patent Application No. 10-2023-0155440 filed on Nov. 10, 2023, in the Korean Intellectual Property Office, the entire contents of which are hereby incorporated by reference.

### BACKGROUND

The inventive concepts relate to a semiconductor memory device.

An electronic system required to store data may require a semiconductor device capable of storing higher-capacity data. Accordingly, research is being conducted on a method of increasing the data storage capacity of the semiconductor device. For example, as one of the methods of increasing the data storage capacity of the semiconductor device, a semiconductor device including memory cells arranged in three dimensions instead of memory cells arranged in two dimensions has been proposed.

### SUMMARY

Some example embodiments provide to a semiconductor memory device with improved reliability and/or integration.

The present disclosure is not limited to the objects mentioned above, and other problems not mentioned will be clearly understood by those skilled in the art from the description below.

According to example embodiments, a semiconductor memory device may include a substrate, a stacked structure including semiconductor patterns stacked in a vertical direction with respect to an upper surface of the substrate, bit lines in contact with first sides of the semiconductor patterns and extending in a first direction parallel to the upper surface of the substrate, common source lines in contact with second sides of the semiconductor patterns and extending in the first direction, word lines penetrating the stacked structure and arranged two-dimensionally, and data storage patterns between the word lines and the stacked structure.

According to example embodiments, a semiconductor memory device may include a substrate, first and second stacked structures spaced apart in a first direction on the substrate, and including semiconductor patterns stacked in a direction perpendicular to an upper surface of the substrate, bit lines in contact with first sides of the semiconductor patterns of the first and second stacked structures and extending in a first direction parallel to the upper surface of the substrate, common source lines in contact with second sides of the semiconductor patterns of the first and second stacked structures and extending in the first direction, a plurality of first word lines penetrating the first stacked structure, a plurality of second word lines penetrating the second stacked structure, first data storage patterns between the first word lines and the first stacked structure, and second data storage patterns between the second word lines and the second stacked structure.

Specific details of other example embodiments are included in the detailed description and drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic perspective view of a semiconductor memory device according to example embodiments of the inventive concepts.

FIG. 2 is a diagram illustrating a schematic cell array of a semiconductor memory device according to example embodiments of the inventive concepts.

FIG. 3 is a circuit diagram of a memory cell array of a semiconductor memory device according to example embodiments of the inventive concepts.

FIG. 4 is a perspective view illustrating a semiconductor memory device according to example embodiments of the inventive concepts.

FIG. 5 is a perspective view illustrating a semiconductor memory device according to example embodiments of the inventive concepts.

FIG. 6 is a plan view of a semiconductor memory device according to example embodiments of the inventive concepts.

FIG. 7 is a plan view of a semiconductor memory device according to example embodiments of the inventive concepts.

FIG. 8A is a cross-sectional view taken along line A-A′ of FIG. 7.

FIG. 8B is a cross-sectional view taken along line B-B′ of FIG. 7.

FIG. 8C is an enlarged view of portion ‘P1’ in FIG. 8A.

FIGS. 9 and 10 are plan views of semiconductor memory devices according to various example embodiments of the inventive concepts.

FIG. 11 is a diagram for explaining a write operation of a semiconductor memory device according to example embodiments of the inventive concepts.

FIG. 12 is a diagram for explaining a read operation of a semiconductor memory device according to example embodiments of the inventive concepts.

FIGS. 13 to 18 are cross-sectional views for illustrating a method of manufacturing a semiconductor memory device according to example embodiments of the inventive concepts.

### DETAILED DESCRIPTION

Hereinafter, a semiconductor memory device according to example embodiments of the inventive concepts will be described in detail with reference to the drawings.

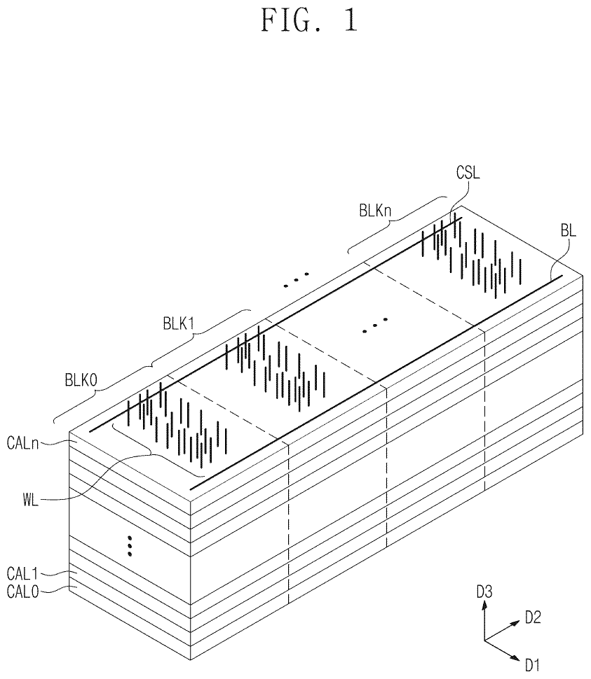

FIG. 1 is a schematic perspective view of a semiconductor memory device according to example embodiments of the inventive concepts.

Referring to FIG. 1, a memory cell array may include a plurality of memory blocks BLK0 to BLKn. The memory blocks BLK0 to BLKn read or write data from the selected memory block in response to a corresponding block selection signal.

Each of the memory blocks BLK0, BLK1 to BLKn may include a plurality of cell array layers CAL1, CAL2, . . . , and CALn that are stacked in a third direction D3 normal to a plane defined by first and second directions D1 and D2 that intersect each other. Each of the cell array layers CAL1, CAL2, . . . , and CALn may include a plurality of memory cells arranged in a plane defined by the first and second directions D1 and D2 that intersect each other. Each memory cell may include a data storage element.

Each of the memory blocks BLK0, BLK1 to BLKn may include word lines WL extending in a third direction D3 perpendicular to the first and second directions D1 and D2. The word lines WL may be commonly provided to the plurality of cell array layers CAL1, CAL2, . . . , and CALn.

Each of the cell array layers CAL1, CAL2, . . . , and CALn may include a bit line BL and a common source line CSL extending in parallel in the second direction D2. In each cell array layer CAL1, CAL2, . . . , and CALn, a plurality of memory cells may be randomly or regularly arranged on a plane defined by the first and second directions D1 and D2.

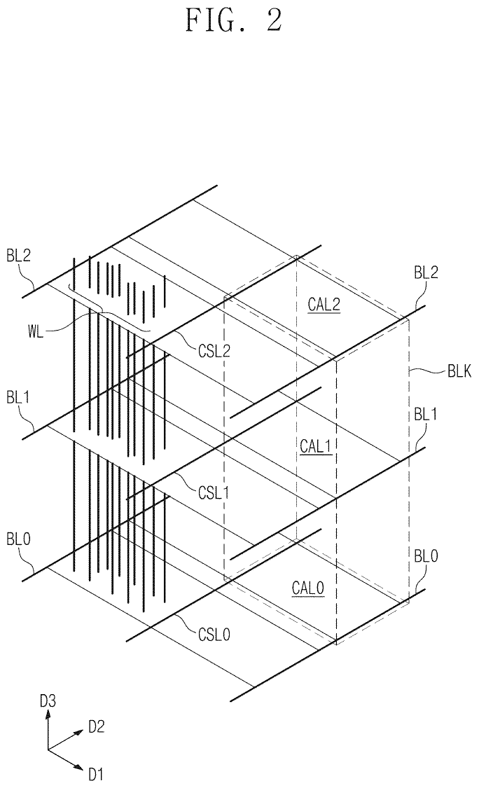

FIG. 2 is a diagram illustrating a schematic cell array of a semiconductor memory device according to example embodiments of the inventive concepts.

Referring to FIG. 2, memory blocks BLK may be arranged in a first direction D1 and a second direction D2, and memory blocks BLK adjacent to the first direction D1 may share a common source line CSL or a bit line BL.

The common source line CSL and the bit line BL may extend side by side in the second direction D2, and a pair of bit lines BL and common source line CSL may be commonly provided to the memory blocks BLK arranged in the second direction D2.

As described above, each of the memory blocks BLK may include cell array layers CAL0, CAL1, and CAL2 stacked in a third direction D3 perpendicular to the first and second directions D1 and D2. The cell array layers CAL0, CAL1, and CAL2 of each memory block BLK may share word lines WL extending in the third direction D3.

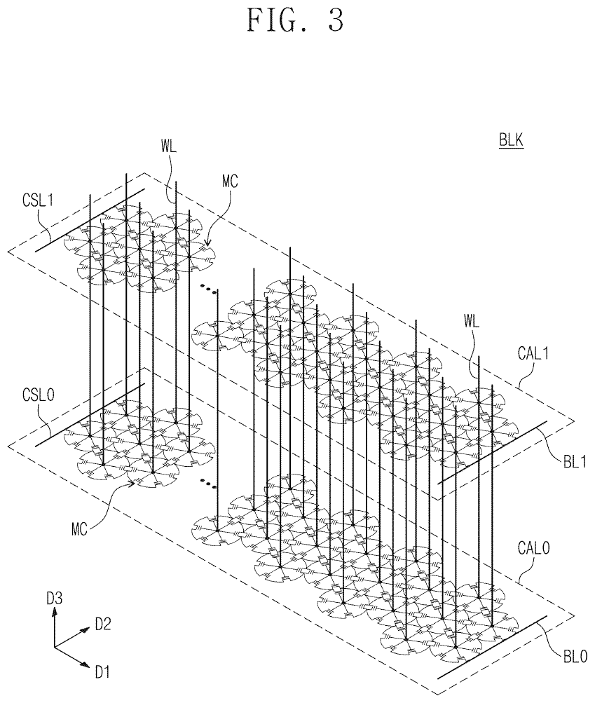

FIG. 3 is a circuit diagram of a memory cell array of a semiconductor memory device according to example embodiments of the inventive concepts.

Referring to FIG. 3, a memory cell array may include a plurality of memory blocks BLK, as previously described with reference to FIG. 1, and each memory block BLK may include a plurality of cell array layers CAL0 and CAL1 stacked in the third direction D3, and each of the cell array layers CAL0 and CAL1 may include memory cells MC arranged in a plane defined by first and second directions D1 and D2 that intersect each other.

Each memory cell MC may include a plurality of cell transistors controlled by one word line. Each cell transistor may include a data storage element.

Channels of cell transistors of adjacent memory cells MC in each cell array layer CAL0 and CAL1 may be electrically connected to each other by voltage applied to the word lines WL. A current path may be formed between one selected bit line BL and one selected common source line CSL through the channels of the cell transistors.

According to example embodiments, in each of the cell array layers CAL0 and CAL1, the number of storage nodes in each memory cell MC may be variously changed depending on an arrangement of the word lines WL. For example, when the word lines WL are arranged in a honeycomb shape from a plan view, each memory cell MC may include six storage nodes.

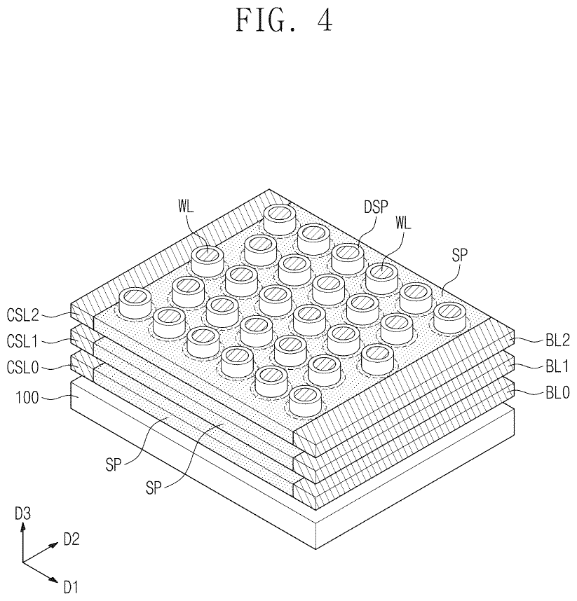

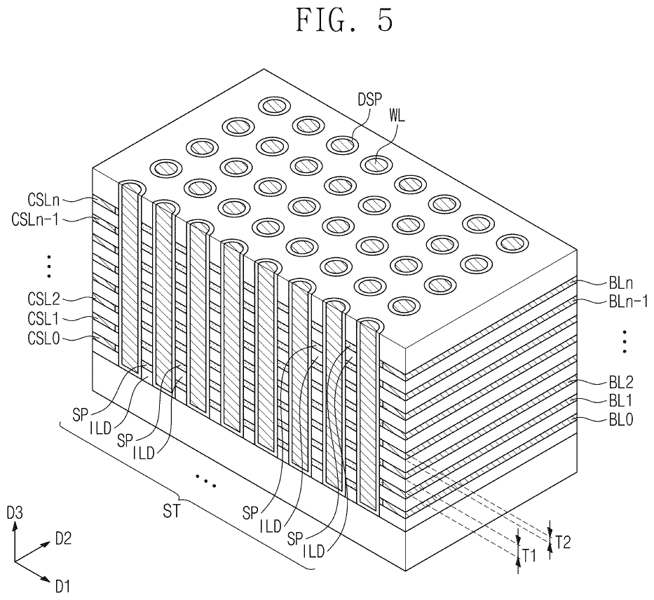

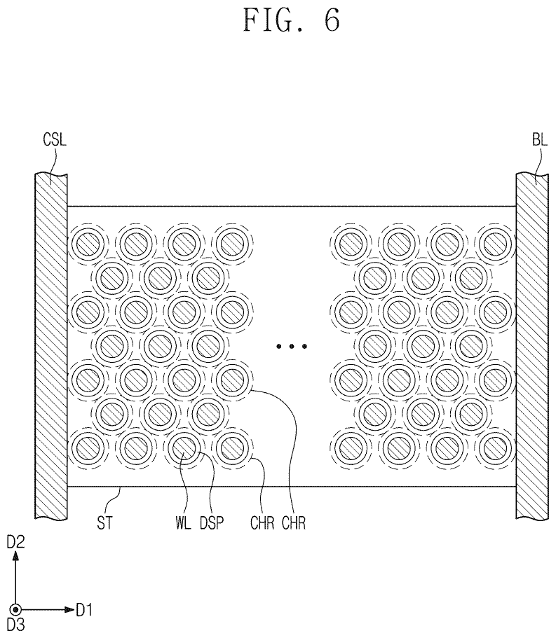

FIG. 4 is a perspective view illustrating a semiconductor memory device according to example embodiments of the inventive concepts. FIG. 5 is a perspective view illustrating a semiconductor memory device according to example embodiments of the inventive concepts. FIG. 6 is a plan view of a semiconductor memory device according to example embodiments of the inventive concepts.

Referring to FIGS. 4 and 5, a stacked structure ST may be disposed on a substrate 100.

The substrate 100 may be one of a material with semiconductor properties (e.g., a silicon wafer), an insulating material (e.g., glass), a semiconductor covered by an insulating material, or a conductor. For example, the substrate 10 may be a silicon wafer having a first conductivity type.

The stacked structure ST may include interlayer insulating layers ILD and semiconductor patterns SP alternately stacked in a third direction D3 perpendicular to an upper surface of the substrate 100.

The semiconductor patterns SP may include at least one of a semiconductor layer, a silicide layer, and a metal layer doped with impurities. As an example, the semiconductor patterns SP may include a polycrystalline silicon layer doped with a first conductivity type impurity.

As another example, the semiconductor patterns SP may include an oxide semiconductor material. As an example, the oxide semiconductor material may include at least one of indium (In), gallium (Ga), zinc (Zn), and tin (Sn). For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. As an example, the semiconductor patterns SP may include indium gallium zinc oxide (IGZO). The semiconductor patterns SP may include a single layer or multiple layers of the oxide semiconductor. The semiconductor patterns SP may include an amorphous, crystalline, or polycrystalline oxide semiconductor.

The interlayer dielectric layers ILD may include a silicon oxide layer and/or a low dielectric layer. Among the interlayer insulating layers ILD, the lowest interlayer insulating layer ILD may be in contact with the upper surface of the substrate 100.

In example embodiments, the interlayer insulating layers ILD may have a minimum first thickness T1 between the semiconductor patterns SP, and each of the semiconductor patterns SP may have a second thickness T2 that is smaller than the first thickness T1. That is, the second thickness T2 of each semiconductor pattern SP may be smaller than a spacing T1 between vertically adjacent semiconductor patterns SP.

The second thickness T2 of the semiconductor patterns SP may be determined to form a channel region around the corresponding word line WL such that the upper surface of the semiconductor pattern SP is inverted by an operating voltage applied to the corresponding word line WL.

Each of the semiconductor patterns SP may have first and second side surfaces facing each other in the first direction D1. The first side of each semiconductor pattern SP may be in contact with the bit lines BL0 to BLn, and the second side of each semiconductor pattern SP may be in contact with the common source lines CSL0 to CSLn.

The bit lines BL0 to BLn may be vertically stacked on the substrate 100, and the bit lines BL0 to BLn may extend in the second direction D2 parallel to the upper surface of the substrate 100. Each of the bit lines BL0 to BLn may be disposed between vertically adjacent interlayer insulating layers ILD. Each of the bit lines BL0 to BLn may be in direct contact with the first side of each semiconductor pattern SP.

The common source lines CSL0 to CSLn may be vertically stacked on the substrate 100, and the common source lines CSL0 to CSLn may extend in the second direction D2 parallel to the upper surface of the substrate 100. The common source lines CSL0 to CSLn may be positioned at the same vertical level as the bit lines BL0 to BLn and the substrate 100, and may be spaced apart from the bit lines BL0 to BLn in the first direction D1. Each of the common source lines CSL0 to CSLn may be disposed between vertically adjacent interlayer insulating layers ILD. Each of the common source lines CSL0 to CSLn may be in direct contact with the second side of each semiconductor pattern SP.

The bit lines BL0 to BLn and the common source lines CSL0 to CSLn may be one of a doped semiconductor material (e.g., doped silicon, doped germanium, etc.), conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.).

The word lines WL may vertically penetrate the stacked structure ST on the substrate 100. The word lines WL may have a pillar shape perpendicular to the upper surface of the substrate 100. Alternatively, the word lines WL may have a ‘U’ shaped vertical cross section.

The word lines WL may be arranged two-dimensionally irregularly or regularly when viewed in a plan view. As an example, the word lines WL may be arranged in a zigzag pattern in the first direction, or alternatively, may be arranged in a matrix form.

Referring to FIG. 6, the word lines WL may be arranged in a honeycomb shape regularly when viewed in a plan view. That is, six word lines WL may be arranged around each word line WL. Here, a spacing between at least three adjacent word lines WL may be the same or substantially the same.

The word lines WL may include at least one of a conductive material (e.g., doped semiconductor, metal, conductive metal nitride, silicide, or nanostructure (such as carbon nanotubes or graphene)).

According to example embodiments, the semiconductor patterns SP around the word lines WL may be inverted by an operating voltage applied to the word lines WL to form channel regions CHR. The channel regions CHR around adjacent word lines WL may overlap or be connected to each other. That is, the channel regions CHR of the memory cells may be connected to each other to form a current path between the bit lines BL0 to BLn and the common source lines CSL0 to CSLn. A spacing between adjacent word lines WL may be less than about twice the maximum width of the channel region CHR. The spacing between adjacent word lines WL may be determined depending on the operating voltage applied to the word lines WL when the semiconductor memory device operates.

Data storage patterns DSP may be respectively disposed between the stacked structure ST and the word lines WL. Each of the data storage patterns DSP may cover a sidewall and a bottom surface of the corresponding word line WL with a uniform thickness. The data storage pattern DSP may extend in a direction perpendicular to the upper surface of the substrate 100.

The data storage patterns DSP may be formed of one thin layer or multiple thin layers. As an example, the data storage patterns DSP may include a charge storage layer that stores data in a NAND flash memory device.

As another example, the data storage patterns DSP may include a ferroelectric material. The ferroelectric material may be made of a dielectric material containing hafnium. The ferroelectric material may include, for example, HfO₂, Si-doped HfO₂ (HfSiO₂), Al-doped HfO₂ (HfAlO₂), HfSiON, HfZnO, HfZrO₂, ZrO₂, ZrSiO₂, HfZrSiO₂, ZrSiON, LaAIO, HfDyO₂, or HfScO₂.

As another example, alternatively, the data storage patterns DSP may include a thin layer for a phase change memory or a thin layer for a variable resistance memory. The Data storage patterns DSP may include, for example, a perovskite compound, transition metal oxide, a phase-change material, a magnetic material, a ferromagnetic material, or an antiferromagnetic material.

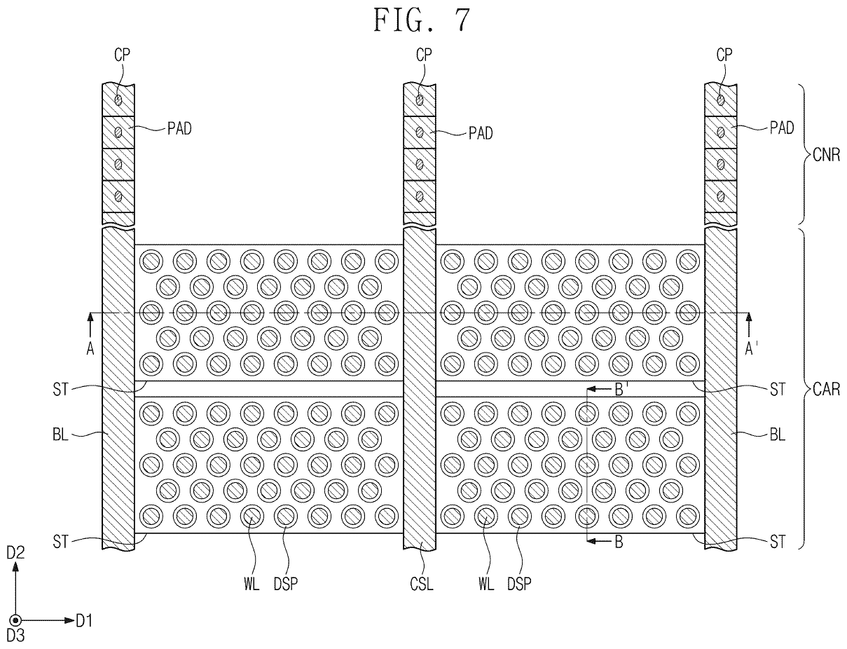

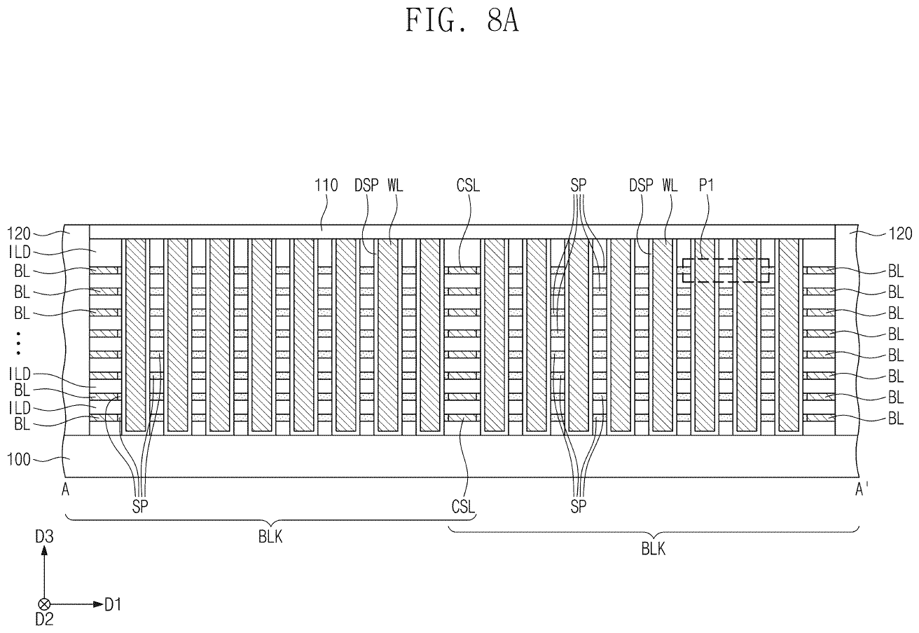

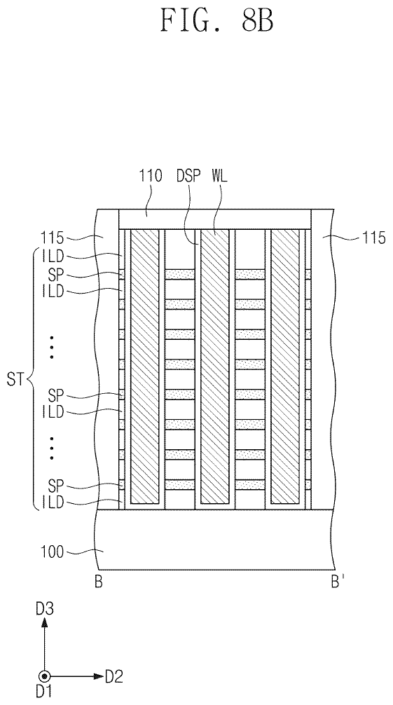

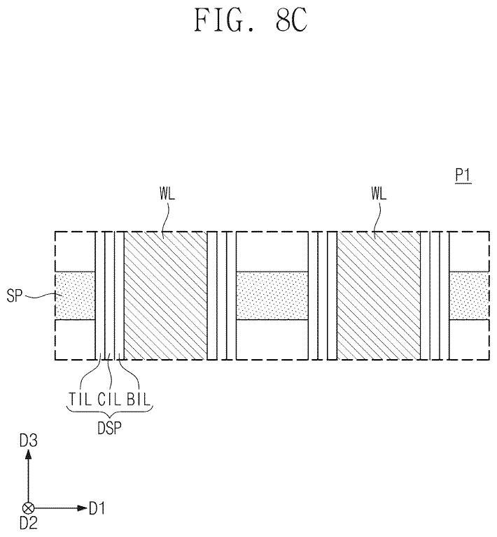

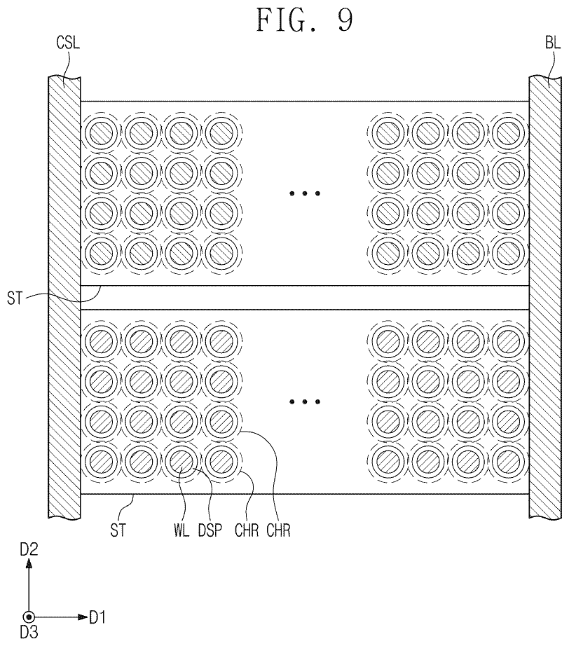

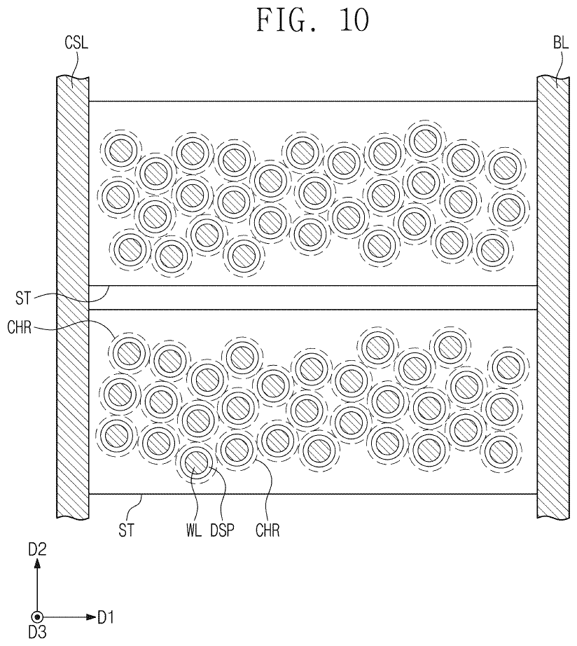

FIG. 7 is a plan view of a semiconductor memory device according to example embodiments of the inventive concepts. FIG. 8A is a cross-sectional view taken along line A-A′ of FIG. 7. FIG. 8B is a cross-sectional view taken along line B-B′ of FIG. 7. FIG. 8C is an enlarged view of portion ‘P1’ in FIG. 8A. FIGS. 9 and 10 are plan views of semiconductor memory devices according to various example embodiments of the inventive concepts.

Referring to FIGS. 7, 8A, and 8B, a substrate 100 may include a cell array region CAR and a connection region CNR adjacent thereto. The substrate 100 may be one of a material with semiconductor properties (e.g., a silicon wafer), an insulating material (e.g., glass), a semiconductor covered by an insulating material, or a conductor.

A stacked structures ST may be disposed on the substrate 100 in the cell array region CAR and may be arranged to be spaced apart from each other in the first direction D1 and the second direction D2.

As described above, each of the stacked structures ST may include interlayer insulating layers ILD and semiconductor patterns SP alternately stacked in the third direction D3 perpendicular to an upper surface of the substrate 100. The semiconductor patterns SP may include the same technical features as the semiconductor memory device described above. Separation insulating patterns 115 may be disposed between adjacent stacked structures ST in the second direction D2. The separation insulating patterns 115 may cover both side walls of each stacked structure ST. For example, the separation insulating patterns 115 may have a single-layer or multi-layer structure of at least one of a silicon oxide layer, a silicon nitride layer, and a silicon oxynitride layer.

Common source lines CSL or bit lines BL may be disposed between adjacent stacked structures ST in the first direction D1.

The common source lines CSL and bit lines BL may be alternately arranged in the first direction D1 in the cell array region CAR. The common source lines CSL and the bit lines BL may continuously extend from the cell array region CAR to the connection region CNR in the second direction D2.

A length of each of the common source lines CSL and bit lines BL may become shorter as a distance from the upper surface of the substrate 100 increases. Each of the common source lines may include a pad portion PAD to which a contact plug CP is connected in the connection region CNR, and the pad portions may form a stepped structure. Likewise, each of the bit lines BL may include a pad portion PAD to which the contact plug CP is connected in the connection region CNR, and the pad portions may form a stepped structure.

The common source lines CSL may be vertically stacked on the substrate 100, and the bit lines BL may also be vertically stacked on the substrate 100. The common source lines CSL and bit lines BL may be positioned at the same level as the semiconductor patterns SP.

Vertical insulating patterns 120 may cover sidewalls of the bit lines BL on the substrate 100. The vertical insulating patterns 120 may continuously extend from the cell array region CAR to the connection region CNR in the second direction D2. For example, the vertical insulating patterns 120 may have a single-layer or multi-layer structure of at least one of a silicon oxide layer, a silicon nitride layer, and a silicon oxynitride layer.

A plurality of word lines WL may vertically penetrate each of the stacked structures ST. The word lines WL may be arranged two-dimensionally regularly or irregularly in the cell array region CAR.

Referring to FIG. 9, the word lines WL may be spaced apart at regular intervals in the first direction D1 and may be spaced apart at the same or substantially the same pitch. In the second direction D2. That is, the word lines WL may be arranged in a matrix form.

Referring to FIG. 10, the word lines WL may be arranged irregularly in the first and second directions. Here, a spacing between adjacent word lines WL may be adjusted such that the channel regions formed around the word lines WL by an operating voltage may overlap or be connected to each other.

In example embodiments, the word lines WL and the semiconductor patterns SP may form a MOS capacitor. In some example embodiments, a data storage pattern DSP constituting the MOS capacitor may be interposed between the word lines WL and the semiconductor patterns SP, and a thickness of the data storage pattern DSP may be adjusted to enable an inversion to be formed in the semiconductor pattern SP by the voltage applied to the word line WL.

The data storage pattern DSP may be interposed between each stacked structure ST and the word lines WL. That is, the data storage pattern DSP may extend between the word lines WL and the semiconductor patterns SP and between the interlayer insulating layers ILD and the word lines WL.

Referring to FIG. 8C, the data storage patterns DSP of a NAND flash memory device may include a tunnel insulating layer TIL, a charge storage layer CIL, and/or a blocking insulating layer BIL. The tunnel insulating layer TIL may be adjacent to the semiconductor patterns SP, and the blocking insulating layer BIL may be adjacent to sidewalls of the word lines WL. The charge storage layer CIL may be interposed between the tunnel insulating layer TIL and the blocking insulating layer BIL.

The charge storage layer CIL may be, for example, a trap insulating layer, a floating gate electrode, or an insulating layer including conductive nano dots. For example, the charge storage layer CIL may include at least one of a silicon nitride layer, a silicon oxynitride layer, a silicon-rich nitride layer, nanocrystalline silicon (nanocrystalline Si), and a laminated trap layer.

The tunnel insulating layer TIL may be one of materials having a larger band gap than the charge storage layer CIL, and the blocking insulating layer BIL may be a high-k dielectric layer such as an aluminum oxide layer or a hafnium oxide layer.

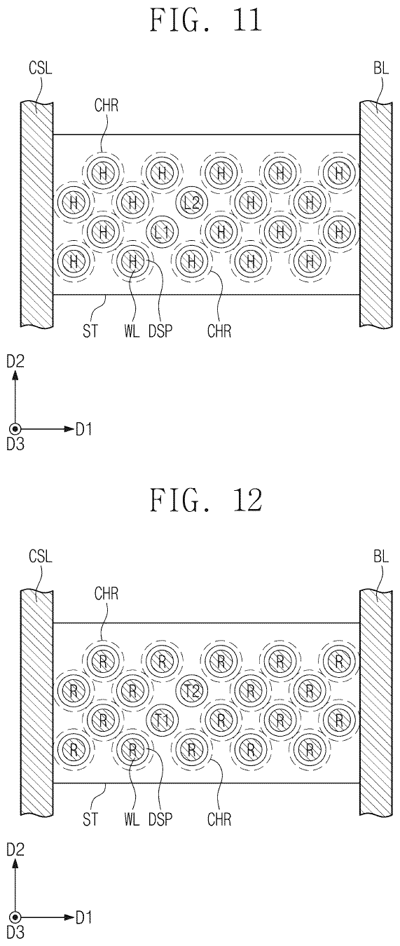

FIG. 11 is a diagram for explaining a write operation of a semiconductor memory device according to example embodiments of the inventive concepts.

Referring to FIGS. 2, 7, 8A, 8B, and 11, a program operation may include selecting one of a plurality of blocks BLK and one of the cell array layers CAL0, CAL1, and CAL2, that is, one of the semiconductor patterns SP in the selected block BLK. That is, a ground voltage may be applied to a selected bit line BL among the plurality of bit lines BL, and a predetermined or alternatively, desired bit line voltage may be applied to the unselected bit lines BL. A ground voltage may be applied to the common source lines CSL.

Additionally, a first operating voltage H may be applied to unselected word lines WL, and second and third operating voltages L1 and L2 may be applied to the at least two selected word lines WL. Here, the first operating voltage H may be a voltage sufficient to form the channel region CHR by inverting the semiconductor pattern SP around the word lines WL, that is, a voltage higher than the threshold voltage of the memory cells. The second and third operating voltages L1 and L2 may be lower than the first operating voltage H and lower than the threshold voltage of the memory cells. Accordingly, the channel regions CHR may be formed around the unselected word lines WL, except around the selected word lines WL. Additionally, the second and third operating voltages L1 and L2 may cause a band-to-band tunneling phenomenon in which the channel regions CHR are not formed around the selected word lines WL and thermal charges are generated around the selected word lines WL. Accordingly, the thermal charges may be injected into the data storage patterns DSP around the selected word lines WL. Here, electrons may be accelerated in a direction of a higher voltage among the second and third operating voltages L1 and L2 and stored in data storage patterns, and holes may be accelerated in the opposite direction and stored in data storage patterns. That is, when the second operating voltage L1 is lower than the third operating voltage L2, electrons may move toward the word line WL to which the third operating voltage L2 is applied, and holes may move toward the word line WL to which the second operating voltage L1 is applied.

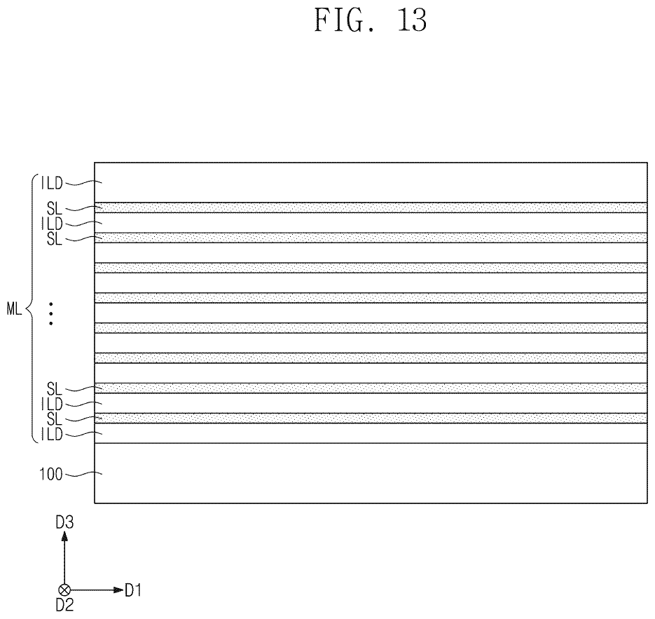

FIG. 12 is a diagram for explaining a read operation of a semiconductor memory device according to example embodiments of the inventive concepts.

Referring to FIGS. 2, 7, 8A, 8B, and 12, a read operation may include sensing a current flowing between a common source line and a selected bit line through a selected semiconductor pattern. In the read operation, a size of the current may be variously changed depending on the data stored in the selected memory cell, and the size of the current may be read from an sense amplifier.

As an example, a read voltage R may be applied to the unselected word lines WL, a first voltage T1 may be applied to one of the selected word lines WL, and a second voltage T2 may be applied to another one of the selected word lines WL. Here, the read voltage R may be a voltage sufficient to invert the semiconductor pattern SP around the word lines WL to form the channel region CHR, that is, a voltage higher than the threshold voltage of the memory cells.

The first voltage T1 and the second voltage T2 may be lower than the read voltage R and may be a voltage that does not form the channel regions CHR around the selected word lines WL. Additionally, the first voltage T1 may be greater than the second voltage T2, and in some example embodiments, data from a memory cell connected to the word line WL to which the first voltage T1 is applied may be read. Alternatively, the second voltage T2 may be greater than the first voltage T1, and in some example embodiments, data from a memory cell connected to the word line WL to which the second voltage T2 is applied may be read.

During such the read operation, an electrical conductivity of adjacent channels may change depending on polarity or amount of charge stored in the data storage pattern DSP of each memory cell, and thus a size of the current sensed in the selected bit line BL may be variously changed.

FIGS. 13 to 18 are cross-sectional views for illustrating a method of manufacturing a semiconductor memory device according to example embodiments of the inventive concepts.

Referring to FIG. 13, a mold structure ML may be formed on a substrate 100 including interlayer insulating layers ILD and semiconductor layers SL alternately stacked.

The semiconductor layers SL may have the same or substantially the same thickness and may be thinner than the interlayer insulating layers ILD.

The interlayer dielectric layers ILD and semiconductor layers SL may be deposited using by thermal chemical vapor deposition (thermal CVD), plasma enhanced chemical vapor deposition (CVD), physical chemical vapor deposition (physical CVD), or atomic layer deposition (ALD) process.

The interlayer dielectric layers ILD may include a silicon oxide layer and/or a low dielectric layer.

The semiconductor layers SL may include, for example, silicon (Si), germanium (Ge), or a mixture thereof, and may be a semiconductor doped with impurities or an intrinsic semiconductor in a state in which no impurities are doped. Additionally, the semiconductor layers SL may have a crystal structure including at least one selected from single crystal, amorphous, and polycrystalline.

The semiconductor layers SL may include, for example, at least one of silicon, germanium, silicon-germanium, or indium gallium zinc oxide (IGZO). In example embodiments, the semiconductor layers SL may include the same semiconductor material as the substrate 100. For example, the semiconductor layers SL may be a single crystal silicon layer or a polycrystalline silicon layer.

The semiconductor layers SL may include an oxide semiconductor, for example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn₂O, YbₓGa_{y}Zn_{z}O, InₓGa_{y}O, or a combination thereof.

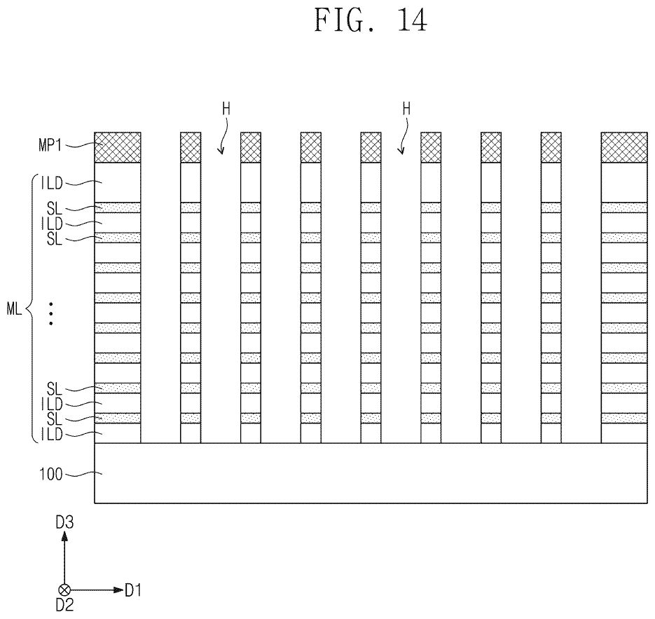

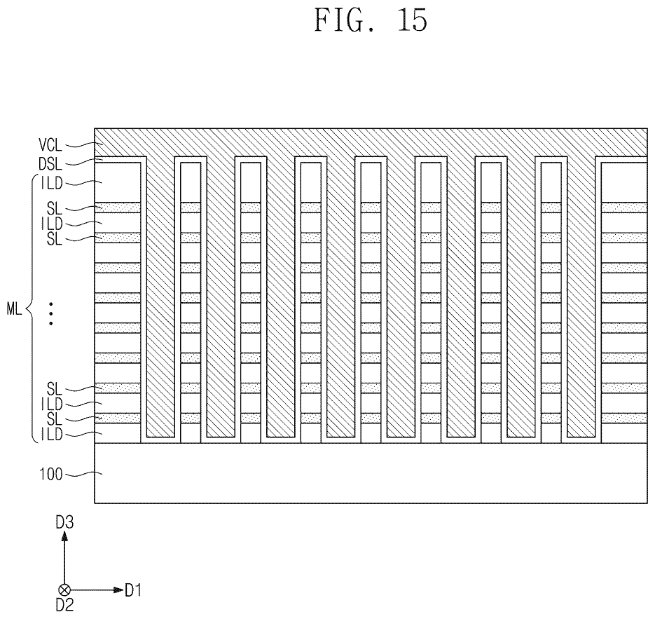

Referring to FIG. 14, a first mask pattern MP1 may be formed on the uppermost interlayer insulating layer ILD of the mold structure ML. The first mask pattern MP1 may have openings corresponding to vertical holes H.

The first mask pattern MP1 may be made of an insulating material that has etch selectivity for the semiconductor layers SL and the interlayer insulating layers ILD. For example, the first mask pattern MP1 may include at least one of a silicon oxide layer, a silicon oxynitride layer, and a silicon nitride layer.

Afterwards, the vertical holes H exposing the substrate 100 may be formed by anisotropically etching the mold structure ML using the first mask pattern MP1 as an etch mask. The vertical holes H may expose an upper surface of the substrate 100, and the upper surface of the substrate 100 below the vertical holes H may be recessed by over-etching during the anisotropic etching. Alternatively, the vertical holes H may expose the lowermost interlayer insulating layer ILD.

An arrangement of the vertical holes H may be random or irregular as described above. In contrast, a spacing between vertical holes H that are adjacent to each other may be constant.

Each of the vertical holes H may have a minimum width at a bottom thereof, and the minimum width may be smaller than a maximum width. Alternatively, each of the vertical holes H may have a width at an upper surface thereof and a width at a bottom surface thereof that are the same or substantially the same.

After forming the vertical holes H, the first mask pattern MP1 may be removed.

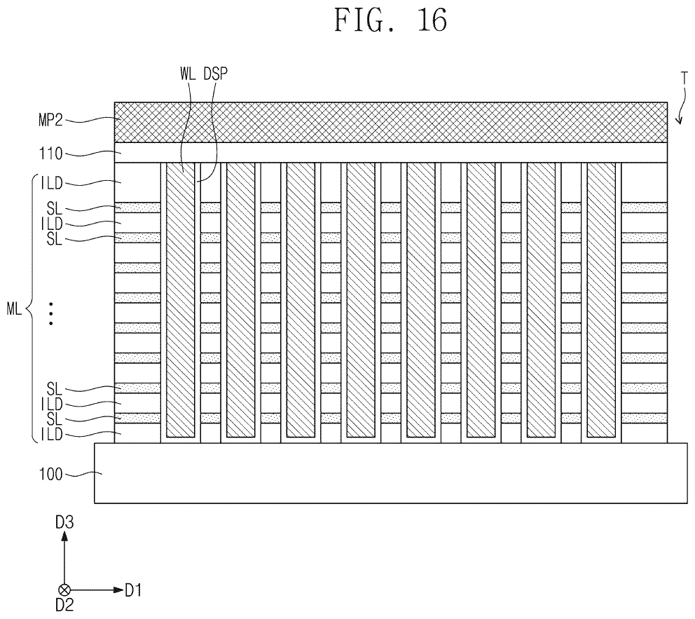

Referring to FIG. 15, a data storage layer DSL and a vertical conductive layer VCL may be sequentially deposited in the vertical holes.

The data storage layer DSL may be deposited to a uniform thickness on bottom surfaces and inner walls of the vertical holes using a chemical vapor deposition (CVD) or atomic layer deposition (ALD) method. The data storage layer DSL may include a blocking insulating layer, a charge storage layer, and a tunneling insulating layer sequentially stacked in vertical holes.

The vertical conductive layer VCL may fill the vertical holes where the data storage layer DSL is formed. The vertical conductive layer VCL may be formed using a chemical vapor deposition (CVD) or atomic layer deposition (ALD) method.

The vertical conductive layer VCL may include at least one selected from of, for example, a doped semiconductor (e.g., doped silicon, etc.), a metal (e.g., tungsten, copper, aluminum, etc.), a conductive metal nitride (e.g., titanium nitride, tantalum nitride, etc.), or a transition metal (e.g., titanium, tantalum, etc.).

Referring to FIG. 16, the data storage layer DSL and the vertical conductive layer VCL may be etched and planarized until the uppermost interlayer insulating layer ILD is exposed. Accordingly, a data storage pattern DSP and a word line WL may be formed within each vertical hole.

The data storage pattern DSP may be in the form of a pipe with a closed bottom or a macaroni shape. The data storage pattern DSP may have a U-shape and may be in contact with the substrate 100 or the lowermost interlayer insulating layer ILD.

After forming the data storage patterns and word lines WL, a first upper insulating layer 110 may be formed on the uppermost interlayer insulating layer ILD. The first upper insulating layer 110 may cover upper surfaces of the word lines WL on the mold structure ML.

Thereafter, a second mask pattern MP2 may be formed on the first upper insulating layer 110. The second mask pattern MP2 may overlap the word lines WL and may have line-shaped openings.

The mold structure ML may be anisotropically etched using the second mask pattern MP2 as an etch mask, to form trenches T exposing the substrate 10. The trenches T may be spaced apart from each other in the first direction D1 and may extend in the second direction D1. The trenches T may expose sidewalls of the semiconductor layers SL and the interlayer insulating layers ILD.

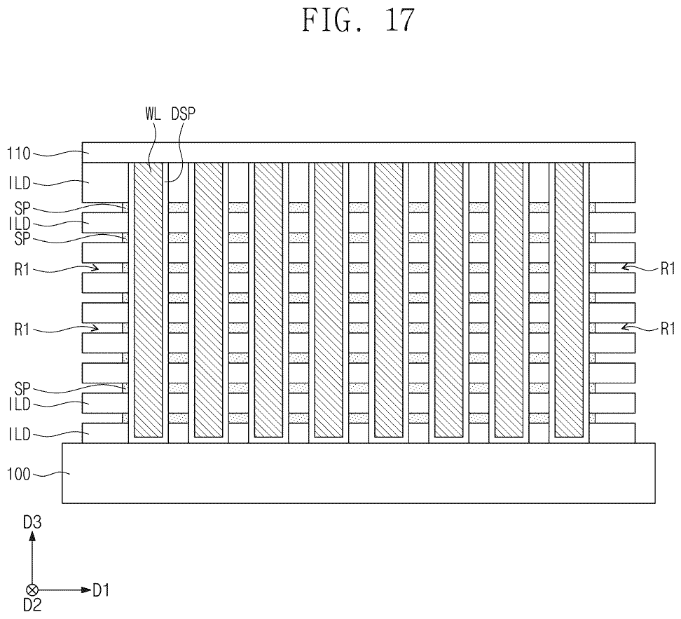

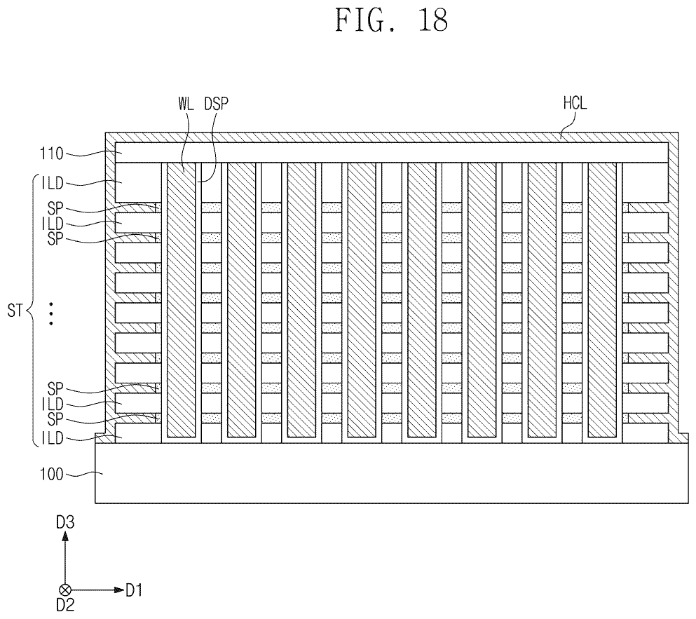

Referring to FIG. 17, portions of the semiconductor layers SL exposed to the trenches T may be selectively removed to form recess regions R between the interlayer insulating layers ILD.

Forming the recess regions R may include isotropically etching portions of the semiconductor layers SL by performing an etching process with etch selectivity on the first upper insulating layer 110, the interlayer insulating layers ILD, and/or the substrate 100.

Each of the recess regions R may be formed between adjacent interlayer insulating layers ILD in the third direction D3 and may extend in the second direction D2. As the recess regions R are formed, semiconductor patterns SP stacked in the third direction D3 may be formed on the substrate 100.

Referring to FIG. 18, a gate conductive layer HCL may be formed to fill the recess regions R. The gate conductive layer HCL may be formed using at least one of thin layer formation techniques that provide excellent step coating properties, and may include at least one of a polycrystalline silicon layer, silicide layer, and metal layer.

Thereafter, the conductive layer may be etched in the trenches T and the conductive layer may remain locally in the recess regions R, to form common source lines and bit lines.

According to example embodiments of the inventive concepts, the semiconductor patterns may be stacked in the direction perpendicular to the upper surface of the substrate, thereby reducing the size of the semiconductor memory device in the vertical direction. In particular, controlling the channel thickness and the spacing between the channels of the memory cell transistor may be advantageous, and the difficulty of the manufacturing process of the semiconductor patterns (e.g., the channels) may be reduced.

The operating voltage may be reduced by using the thermal charge injection phenomenon when operating the semiconductor memory device. Additionally, the number of data bits that are capable of being stored in a unit memory cell may be increased.

While example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor memory device comprising:
a substrate;
a stacked structure including semiconductor patterns stacked in a vertical direction with respect to an upper surface of the substrate;
bit lines in contact with first sides of the semiconductor patterns and extending in a first direction parallel to the upper surface of the substrate;
common source lines in contact with second sides of the semiconductor patterns and extending in the first direction;
word lines penetrating the stacked structure in the vertical direction and arranged two-dimensionally; and
data storage patterns between the word lines and the stacked structure.

2. The semiconductor memory device of claim 1, wherein the word lines are arranged irregularly at intervals in the first direction and in a second direction that is parallel to the upper surface of the substrate and intersects the first direction.

3. The semiconductor memory device of claim 1, wherein the word lines are spaced apart at substantially the same pitch in the first direction.

4. The semiconductor memory device of claim 1, wherein at least three adjacent word lines are spaced apart from each other at substantially the same pitch.

5. The semiconductor memory device of claim 1, wherein the word lines are arranged in a honeycomb shape when viewed in a plan view.

6. The semiconductor memory device of claim 1, wherein the stacked structure further includes interlayer insulating layers interposed between the semiconductor patterns, and
wherein the common source lines and the bit lines are disposed between the vertically adjacent interlayer insulating layers.

7. The semiconductor memory device of claim 1, wherein the stacked structure further includes interlayer insulating layers between the semiconductor patterns, and
the semiconductor patterns have a second thickness that is smaller than a minimum first thickness of the interlayer insulating layers.

8. The semiconductor memory device of claim 1, wherein each data storage pattern surrounds a sidewall and a bottom surface of each of the word lines.

9. The semiconductor memory device of claim 1, wherein the data storage patterns include a tunnel insulating layer, a charge storage layer, and a blocking insulating layer.

10. The semiconductor memory device of claim 1, wherein channel regions are induced in the semiconductor patterns around the word lines by a first operating voltage applied to the word lines.

11. The semiconductor memory device of claim 10, wherein the channel regions of some of the word lines are connected to each other in a direction parallel to the upper surface of the substrate.

12. The semiconductor memory device of claim 1, wherein a first operating voltage is applied to unselected word lines among the word lines,
a second operating voltage lower than the first operating voltage is applied to the selected word line among the word lines,
a programming operation is performed by hot carrier injection into the data storage patterns in a portion of the semiconductor layer around the selected word line.

13. The semiconductor memory device of claim 12, wherein the channel regions are induced in the semiconductor patterns around the unselected word lines by the first operating voltage, and a current path between the selected bit line among the bit lines and the one common source line opposite thereto is formed.

14. A semiconductor memory device comprising:
a substrate;
first and second stacked structures spaced apart in a first direction on the substrate, and including semiconductor patterns stacked in a direction perpendicular to an upper surface of the substrate;
bit lines in contact with first sides of the semiconductor patterns of the first and second stacked structures and extending in a first direction parallel to the upper surface of the substrate;
common source lines in contact with second sides of the semiconductor patterns of the first and second stacked structures and extending in the first direction;
a plurality of first word lines penetrating the first stacked structure;
a plurality of second word lines penetrating the second stacked structure;
first data storage patterns between the first word lines and the first stacked structure; and
second data storage patterns between the second word lines and the second stacked structure.

15. The semiconductor memory device of claim 14, wherein the first word lines are spaced apart from each other such that channel regions induced in the semiconductor patterns around the first word lines to which a first operating voltage is applied overlap and are connected to each other.

16. The semiconductor memory device of claim 14, wherein the first word lines and the second word lines are at irregular intervals in the first direction and in a second direction that is parallel to the upper surface of the substrate and intersects the first direction.

17. The semiconductor memory device of claim 14, wherein the first word lines and the second word lines are in a honeycomb shape when viewed in a plan view.

18. The semiconductor memory device of claim 14, wherein each of the first and second stacked structures further includes interlayer insulating layers between the semiconductor patterns, and
wherein the common source lines and the bit lines are between the vertically adjacent interlayer insulating layers.

19. The semiconductor memory device of claim 14, further comprising a separation insulating pattern disposed on the substrate between the first and second stacked structures in the first direction and covering sidewalls of the first and second stacked structures.

20. The semiconductor memory device of claim 14, wherein the first and second data storage patterns include a charge trap layer, a ferroelectric layer, a ferromagnetic layer, or a variable resistance layer.
